(19) United States
(12) Patent Application Publication
(10) Pub. No.: US 2009/0255577 A1
(43) Pub. Date: Oct. 15, 2009

(54) Conversion Solar Cell

(76) Inventor: Michael Tischler, Phoenix, AZ (US)

Correspondence Address: FOLEY & LARDNER LLP, P.O. BOX 80278, SAN DIEGO, CA, 92138-0278, US

(21) Appl. No.: 12/417,581

(22) Filed: Apr. 2, 2009

Related U.S. Application Data
(60) Provisional application No. 61/042,513, filed on Apr. 4, 2008.

(51) Int. Cl. H01L 31/00

(52) U.S. Cl. 136/255; 136/256

(57) ABSTRACT

A conversion solar cell structure responds to a greater portion of the solar spectrum. The solar-cell structure has a solar cell and a conversion material disposed over the solar cell.

### CROSS-REFERENCE TO RELATED APPLICATION

This patent application claims priority to U.S. Provisional Patent Application No. 61/042,513, entitled “CONVERSION SOLAR CELL,” filed Apr. 4, 2008, which is hereby incorporated by reference in its entirety for all purposes.

### BACKGROUND OF THE INVENTION

This application relates generally to solar cells. More specifically, this application relates to the production and use of solar cells that capture a large portion of the solar spectrum.

One of the issues that arises in the production of solar cells is the size of the solar spectrum to which the cells will respond in converting light energy to electrical energy. In particular, single-junction solar cells only absorb light with an energy greater than the bandgap of the semiconductor that is used for the cell. To increase the use of solar radiation, multifunction solar cells have been used that have two or more cells in series. Each cell is then made of a successively smaller bandgap semiconductor so that a larger portion of the solar spectrum is able to be absorbed by one of the cells. The result is that the structure generates more power than is possible in a single-junction cell.

But multifunction solar cells have complicated structures that lead to high cost and lower yields. An alternative approach that is sometimes proposed is then to use a multiband material, which has more than one conduction band. The use of such materials again results in the absorption of a larger portion of the solar spectrum. In all these cases, though, it would be desirable to capture a larger portion of the solar spectrum without increasing the complexity of the epitaxial structure of the solar cell.

There accordingly still exists a need in the art for improved solar cells that respond to a greater portion of the solar spectrum.

### BRIEF SUMMARY OF THE INVENTION

Embodiments of the invention provide a conversion solar cell structure that responds to a greater portion of the solar spectrum. The solar-cell structure comprises a solar cell and a conversion material disposed over the solar cell. The conversion material may comprise a down-conversion material such as a phosphor or may comprise an up-conversion material. The solar cell may be a single-junction solar cell, a multijunction solar cell, or a multiband solar cell in different embodiments.

Other embodiments of the invention comprise objects and devices comprising the solar cell, such as a device powered by energy generated with the solar cell.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components.

FIG. 1 provides a schematic illustration of a solar-cell structure that may be produced in accordance with embodiments of the invention;

FIGS. 2A-2C illustrate the electronic structure of different types of monocrystalline solar cells; and

FIG. 3 is a flow diagram summarizing methods of generating energy using conversion solar cells.

### DETAILED DESCRIPTION OF THE INVENTION

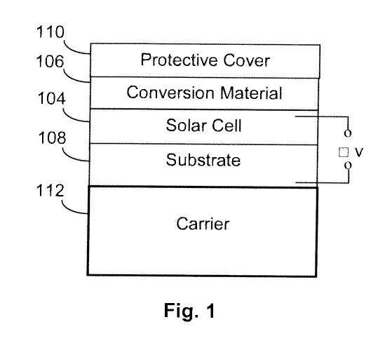

Embodiments of the invention provide solar cells that increase the portion of the solar spectrum that is absorbed through the use of a conversion material formed over the solar cell. The basic concept is illustrated with the structure shown schematically in FIG. 1.

The structure is formed around a substrate 108 that is disposed over a carrier 112, with the solar cell 104 and conversion material 106 formed over the substrate 108. In some instances, a protective cover 110 may also be formed over the conversion material 106 so that the structure as a whole is provided with some protection. This particular structure is shown merely for exemplary purposes and is not intended to be limiting; in various alternative embodiments, different portions of this structure might be omitted, with some embodiments having only the solar cell 104 and conversion material 106, other having the solar cell 104, conversion material 106, and substrate 108, and others having the structure as shown without the protective cover 110. In still other embodiments, a variety of other structures might additionally be included. Whatever the particular structure, the solar cell 104 is combined with conversion material 106 to improve the portion of the solar spectrum that is absorbed.

The inclusion of a conversion layer 106 in the structure acts to convert light of one wavelength that is incident on the structure to a shorter or longer wavelength that is within the absorption band of the underlying solar cell 104. For example, a down-conversion layer could be applied on a solar cell to convert a portion of the higher-energy solar spectrum that is above the absorption band of the underlying solar cell. In one example, the down-conversion material could comprise a phosphor similar to those used in phosphor-based light-emitting diodes. There may be some conversion loss associated with this process, but it may be configured to result in more photons being available than without the conversion layer in the absorption band of interest.

In another example, the conversion layer 106 comprises an up-conversion material that converts a portion of the lower-energy solar spectrum that is below the absorption band of the underlying solar cell.

Other aspects of the structure shown in FIG. 1 may be provided in a wide number of variations without departing from the intended scope of the invention. For example, there are a number of different substrates 108 that may be used in different embodiments, including elemental or binary group-IV substrates such as silicon, germanium, and SiC; III-V compounds such as GaAs, GaP, AlAs, AlP, InGaAs, InGaP, IV-VI compounds such as ZnSe, and other substrate materials such as sapphire.

In at least some embodiments, the conversion material may also be substantially transparent to a portion of the solar spectrum, so that a portion of the spectrum is converted into the range usable by the underlying solar cell and a portion that is directly usable by the underlying solar cell is transmitted through the conversion material. In different embodiments, there may be a tradeoff between thickness and transparency of the conversion material and the efficiency of the cell, taking into account both the directly transmitted and converted light.

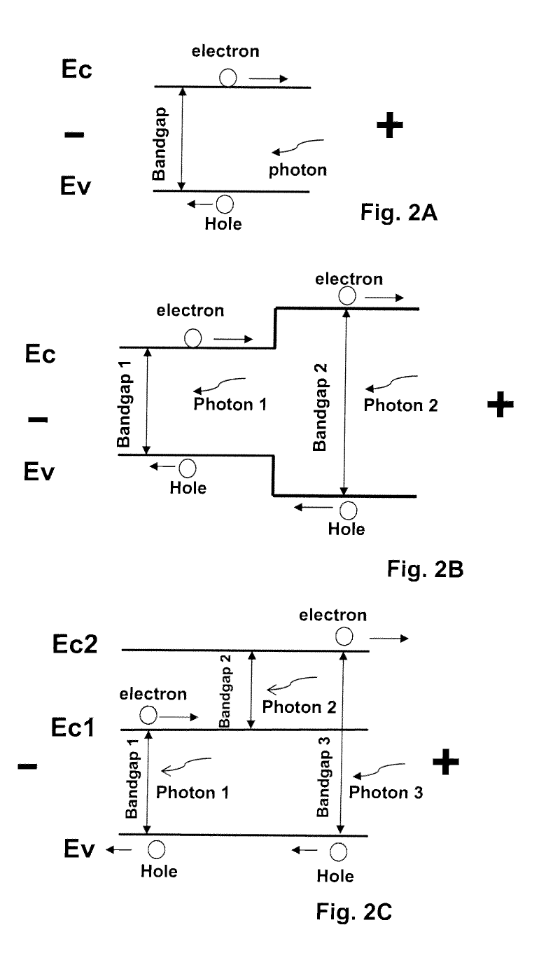

The solar cell 104 itself may also comprise any of a variety of electronic structures such as those illustrated in FIG. 2. The simplest structure, illustrated in FIG. 2A, makes use of a single junction. Specifically, a single bandgap material is used to capture a portion of the solar spectrum, with photons that have an energy greater than the bandgap of the material being absorbed to create an electron-hole pair that produces a DC current under the action of an electric field. The conversion efficiency for a single-junction cell has a peak near the bandgap of the active region and decreases rapidly for higher energies. Using a single bandgap to convert a substantial portion of the solar spectrum is therefore relatively inefficient, with a theoretical maximum efficiency of 35% but with typical efficiencies actually using this technology being on the order of 15-20%.

Conversion of the available solar spectrum to electrical energy may be improved by using multiple junctions. This can be accomplished by engineering multiple bandgaps into a single cell. This is illustrated schematically with FIG. 2B, in which individual cells with different bandgaps are grown monolithically on top of one another with the largest bandgap material located at the top of the stack. With this approach, a larger portion of the incident energy is able to be absorbed, thereby increasing the total efficiency of the cell The most popular approach to multijunction cells currently being researched are based on lattice-matched GaInP/GaAs double-junction cells and GaInP/GaAs/Ge triple junction cells and achieve maximum efficiencies on the order of 30-35% in practice. The theoretical maximum efficiency for the use of three-junction cells is 56%.

A more sophisticated approach that has been explored at least theoretically is a multiple-Band technique in which the number of bandgaps within a single cell is increased without the use of multiple materials. Introduction of a small fraction of highly electronegative atoms into a host semiconductor material has been shown to dramatically alter the electronic band structure of the host material by splitting the conduction band into two sub-bands. Because of the interaction between the two subbands, one subband is pushed to an energy higher than that of the bandgap of the host semiconductor and the other subband is pushed to a lower energy. This results in the creation of an additional energy level in the base structure to provide for three optical transitions as shown in FIG. 2C. The structure is therefore functionally equivalent to a triple-junction cell. The theoretical maximum efficiency using this approach is approximately 63%. The inclusion of still additional bands using this technique promises even higher efficiencies, with four-band approaches providing a theoretical maximum efficiency of 72%.

In some embodiments, one or more of the solar cells comprises a dilute nitride absorbing layer and an emitter layer. The dilute nitride absorbing layer may be provided as a ternary, quaternary, quinary, or higher alloy. But in addition to including at least one group-III element and at least one group-V element, the absorbing layer in these embodiments includes nitrogen. Examples of group-III elements that may be used comprise Ga. In, and Al, among others, and examples of group-V elements that may be used comprise As, P, Sb, and S, among others. Thus, the absorbing layer comprises a material with the general formula GaₓIn_{y}Al_{z}NₐAs_{b}P_{c}Sb_{d}Sₑ, where x<1, y<1, z<1, 0.0001<a<0.1, b<1, c<1, d<1, and e<1. An exemplary range for a concentration of the nitrogen in the absorbing layer is 0.01-10.0 at. %. The electrically active carrier concentration in illustrative embodiments is between 10¹⁶ and 5×10¹⁸ cm⁻³. The absorbing layer functions by absorbing photons to create electron-hole pairs. Further discussion of this absorption mechanism is described in greater detail below. A suitable thickness for the absorbing layer in different embodiments is within the range of 1.0-10.0 μm.

In some embodiments, the solar cells comprise doped or undoped SiC, GaN, GaP, GaS, AlAs, AlP, CdS, ZnTe, ZnSe, ZnS, or an alloy thereof. These materials may be doped, for example with about 0.01% to about 10% N.

The emitter may be doped using carriers of the opposite charge to those used in the absorbing layer. For example, in those embodiments where the absorbing layer is n-type doped, the emitter may be p-type doped. In one such group of examples, the emitter has an electrically active carrier concentration in the range 10¹⁷-10²⁰ cm⁻³. The emitter layer may advantageously have a larger bandgap than the absorbing layer, thereby minimizing surface recombination as described further below. Examples of materials that may be used for a p-type emitter layer include GaP, AlAs, AlInP, AlPas, AlInAsP, InGaP, and ZnSe, among others. A suitable thickness of the emitter layer is between 0.05 and 1.0 μm.

There are a number of other general considerations relevant to specific compositions in the solar-cell structure. For example, consider the case where the dilute nitride absorbing layer comprises GaNₓAs_{y}P_{1-x-y}. For such a material system to exhibit multiband properties x and y should be selected so that there is sufficient incorporation of active nitrogen to separate the conduction band from the intermediate band. This may be achieved in embodiments of the invention with x>0.01, such as between 0.01 and 0.1. At the same time, the phosphorous concentration may be selected to provide a direct F bandgap that is less than the indirect X bandgap. This is achieved in specific embodiments with 0.35<(1−x−y)<0.50. In particular embodiments, 0.005≦x≦0.050 and 0.3≦y≦0.7. Additionally, the compositions within this range may be selected to achieve relatively higher carrier mobility in the Ec2 conduction band, and minimize the conduction-band discontinuities, enhancing transport through the device.

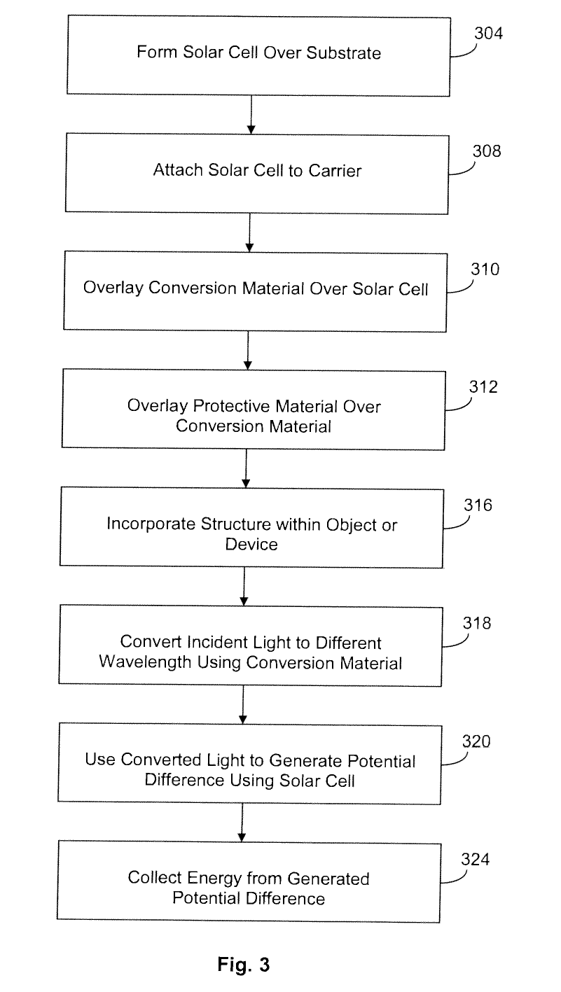

Irrespective of the specific electronic structure used, the solar cell 104 is designed to capture and convert a portion of the solar spectrum to electricity. A general overview of methods of the invention is accordingly provided with the flow diagram of FIG. 3. The specific flow diagram shown in FIG. 3 is intended only to be exemplary. It shows certain specific steps and an order for those steps, but it should be recognized that in various alternative embodiments additional steps might be performed, some steps might be omitted, and/or the order of the steps might be changed.

At block 304, a solar cell is formed over a substrate. The formation of the solar cell may be performed in a number of different ways, one example being the use of an epitaxial-growth process that uses chemical-vapor deposition or other growth techniques. In alternative embodiments, a previously formed solar cell may be bonded or otherwise attached to the substrate. At block 308, the combined solar cell and substrate is attached to the carrier and the conversion material overlaid over the solar cell at block 310. In embodiments where a protective cover is used, the protective material is overlaid over the conversion material at block 312.

The resulting structure may be incorporated within an object or device at block 316. There are a number of different objects or devices that may find utility for the solar-cell structure, including both portable and nonportable objects and devices, terrestrial and space-based objects and devices, and other objects and devices. Merely by way of example, some applications include incorporation of the solar-cell structure on office buildings, on spacecraft, on cellular telephones, on motor vehicles, and as stand-alone energy-generation devices. Whatever the specific application, the light incident on the solar cell is up- or down-converted at block 318 to different wavelengths, allowing the converted light to be used in generating a potential difference with the solar cell at block 320. Energy is collected from the generated potential difference at block 324. Energy collected by this process may subsequently be used directly in powering the device to which the solar cell is attached, or by storing it chemically in a battery or in another form in some other energy-storage device. For instance, some of the devices identified above may be powered by energy generated from light incident on a solar cell comprised by the device.

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed is:

1. A solar-cell structure comprising:
a solar cell; and
a conversion material disposed over the solar cell.

2. The solar-cell structure recited in claim 1 wherein the conversion material comprises a down-conversion material.

3. The solar-cell structure recited in claim 2 wherein the down-conversion material comprises a phosphor.

4. The solar-cell structure recited in claim 1 wherein the conversion material comprises an up-conversion material.

5. The solar-cell structure recited in claim 1 wherein the solar cell is a single-junction solar cell.

6. The solar-cell structure recited in claim 1 wherein the solar cell is a multijunction solar cell.

7. The solar-cell structure recited in claim 1 wherein the solar cell is a multiband solar cell.

8. The solar-cell structure recited in claim 1 wherein the solar cell comprises SiC, GaN, GaP, GaS, AlAs, AlP, CdS, ZnTe, ZnSe, ZnS, or an alloy thereof.

9. The solar-cell structure recited in claim 8 wherein the solar cell further comprises N having a concentration in a range between about 0.01% and 10%.

10. The solar-cell structure recited in claim 1 wherein the solar cell comprises an absorbing layer and an emitter layer.

11. The solar-cell structure recited in claim 10 wherein in absorbing layer comprises a dilute nitride absorbing layer having a semiconducting alloy with a group-III element, a group-V element, and nitrogen.

12. The solar-cell structure recited in claim 11 wherein the dilute nitride absorbing layer comprises a nitrogen concentration between 0.01 at. % and 10.0 at. %.

13. The solar-cell structure recited in claim 11 wherein the dilute nitride absorbing layer comprises an electrically active carrier concentration between 10¹⁶ and 5×10¹⁸ cm³.

14. The solar-cell structure recited in claim 10 wherein the dilute nitride absorbing layer comprises an electrically active carrier concentration between 10¹⁶ and 5×10¹⁸ cm³.

15. The solar-cell structure recited in claim 1 wherein:
the solar cell comprises GaₓIn_{y}Al_{Z}NₐA_{sb}P_{c}Sb_{d}Sₑ;
x<1;
y<1;
z<1;
0.0001<a<0.01;
b<1;
c<1;
d<1; and
e<1.

16. The solar-cell structure recited in claim 1 wherein:
the substantially transparent solar cell comprises Ga, As, N, and P; and the N has a concentration in the range of about 0.01% to about 10%.

17. An object comprising the solar cell recited in claim 1.

18. A device comprising the solar cell recited in claim 1 and powered by energy generated with the solar cell recited in claim 1.

19. A method of generating electrical energy, the method comprising:
receiving light at a conversion material;
converting a wavelength structure of the received light with the conversion material;
receiving the converted light at a solar cell;
generating a potential difference with the solar cell from the received converted light; and
producing the electrical energy from the generated potential difference.

20. The method recited in claim 19 wherein converting the wavelength structure of the received light comprises down-converting the wavelength structure of the received light.

21. The method recited in claim 21 wherein converting the wavelength structure of the received light comprises up-converting the wavelength structure of the received light.
